(19) United States
(12) Patent Application Publication
(10) Pub. No.: US 2015/0021735 A1
(43) Pub. Date: Jan. 22, 2015

(54) SEMICONDUCTOR DEVICE AND METHOD OF MANUFACTURING THE SAME

(71) Applicants: Founder Microelectronics International Co., Ltd, Shenzhen (CN); PEKING UNIVERSITY FOUNDER GROUP CO., LTD., Beijing (CN)

(72) Inventor: Zhengfeng WEN, Beijing (CN)

(73) Assignees: Founder Microelectronics International Co., Ltd, Shenzhen (CN); PEKING UNIVERSITY FOUNDER GROUP CO., LTD., Beijing (CN)

(21) Appl. No.: 14/092,150

(22) Filed: Nov. 27, 2013

(30) Foreign Application Priority Data
Jul. 19, 2013 (CN) 201310306522.X

(51) Int. Cl. H01L 29/06; H01L 21/762

(52) U.S. Cl. CPC H01L 29/0649; H01L 21/76205
USPC 257/510; 438/425

(57) ABSTRACT

The invention provides a semiconductor device and a method of manufacturing the same. The inventive method includes: 1) forming a pad oxide layer on a substrate; 2) forming on the pad oxide layer a barrier layer with an isolation region pattern exposing the surface of the pad oxide layer; 3) injecting ions so that the ions enter the substrate through the surface of the pad oxide layer exposed by the isolation region pattern; 4) performing heat treatment the substrate to transversely diffuse the ions in the substrate to form an ion injection layer; 5) etching the pad oxide layer and the ion injection layer using the barrier layer with the isolation region pattern as a mask to form a shallow trench isolation region on the substrate; and 6) forming a field oxide layer in the shallow trench isolation region of the substrate. The invention method involves a simple process and can significantly the length of beck in the semiconductor device without lowering the thicknesses of the pad oxide layer and the field oxide layer to thereby ensure the area of an active area of the semiconductor device and can be widely applicable to the field of MOS manufacturing.

This application claims the benefit of Chinese Patent Application No. 201310306522.X, filed on Jul. 19, 2013, which is incorporated herein by reference.

### FIELD OF THE INVENTION

The present invention relates to the field of semiconductor manufacturing and particularly to a semiconductor device and a method of manufacturing the same.

### BACKGROUND OF THE INVENTION

At present, Local Oxidation of Silicon (LOCOS) is commonly performed for isolation in a process of manufacturing a Metal Oxide Semiconductor (MOS) above 0.35 micrometers, where local oxidation of silicon is performed using nitride as a mask, and a thick oxide layer (i.e., field oxide layer) is grown on other area than an area in which an active transistor is formed (i.e., an active area) so as to prevent leakage, interference, short-circuit and other phenomena from occurring between devices.

A traditional LOCOS process generally includes the steps of: 1) forming a pad oxide layer (typically of silicon dioxide) on a silicon substrate; 2) depositing a silicon nitride layer on the pad oxide layer; 3) coating the silicon nitride layer with photo-resist and exposing photo-resist using a mask defined with an isolation region pattern and then developing photo-resist to form a photo-resist layer with the isolation region pattern; 4) etching the silicon nitride layer using the photo-resist layer with the isolation region pattern as a mask to remove the part of the silicon nitride layer inside the isolation region pattern; and 5) growing a field oxide layer using the part of silicon nitride outside the isolation region pattern as a mask of local oxide. FIG. 1 illustrates a schematic structural diagram of a cross section of a semiconductor device prepared in the convention process, which includes a silicon substrate 1, silicon dioxide 2 located on the surface of the silicon substrate 1; silicon nitride 3 located on the silicon dioxide 2, and a field oxide layer 4 located in the silicon substrate 1 to isolate an active area.

However diffusion of oxygen in silicon dioxide is an isotropic process, and in the course of local oxidation, oxygen may be diffused transversely through the silicon dioxide layer below silicon nitride, and silicon dioxide may be grown below the silicon nitride layer close to an etch window. Due to thicker silicon consumed in the oxide layer, oxide grown below the nitride mask may raise the edge of nitride, and this phenomenon is referred to as a “beak effect”. With the foregoing traditional process, the grown filed oxide layer 4 may be diffused transversely for penetration below silicon nitride 3 to thereby form a neck area 5 near the edge of silicon nitride 3, which may occupy an area of the active area of the device, thus lowering the integration level of the device. Particularly the length of the neck area is closely related to the thickness of the field oxide layer, and the area of the active area of the device finally occupied by the formed neck area may be considerable in a semiconductor chip with a large number of field oxide layer partitions.

In order to address the foregoing problem, it is common in the prior art to control the length of the “beak” by lowering the thickness of the pad oxide layer below silicon nitride, and generally the “neck” will be shorter with a lower thickness of the pad oxide layer. However the thickness of the pad oxide layer is constrained by silicon nitride in that the pad oxide layer being too thin may tend to result in an increased stress applied by silicon nitride onto the surface of the silicon substrate and consequently can not act to protect the silicon substrate.

### SUMMARY OF THE INVENTION

The invention provides a semiconductor device and a method of manufacturing the same, and the inventive method can significantly lower the length of the beak formed in the traditional LOCOS process without changing the thickness of the field oxide layer to thereby effectively ensure the area of the active area in the semiconductor device and improve the integration level of the semiconductor device.

A semiconductor device according to the invention includes:
a substrate with a shallow trench isolation region arranged thereon, wherein an ion injection layer is arranged around the shallow trench isolation region;
a pad oxide layer, located on the substrate, with an isolation region pattern exposing the shallow trench isolation region;
a barrier layer, located on the pad oxide layer, with the isolation region pattern exposing the shallow trench isolation region; and
a field oxide layer located in the shallow trench isolation region.

In the semiconductor device according to the invention, the ion injection layer extends transversely outward by 0.07-0.13 μm around the shallow trench isolation region, and the ions are nitrogen ions.

Furthermore the substrate of the invention can also be referred to a base, etc., and in a particular implementation, the substrate is a silicon substrate; the pad oxide layer is with a thickness of 200-500 Å and of a material of silicon oxide; the barrier layer is a nitride layer with a thickness of 1500-3000 Å and of a material of silicon nitride; and the field oxide is with a thickness of 5000-15000 Å and of a material of silicon oxide.

The invention further provides a method of manufacturing a semiconductor device, the method including the steps of:
1) forming a pad oxide layer on a substrate;
2) forming on the pad oxide layer a barrier layer with an isolation region pattern exposing the surface of the pad oxide layer;
3) injecting ions so that the ions enter the substrate through the surface of the pad oxide layer exposed by the isolation region pattern;
4) performing heat treatment the substrate to transversely diffuse the ions in the substrate to form an ion injection layer;
5) etching the pad oxide layer and the ion injection layer using the barrier layer with the isolation region pattern as a mask to form a shallow trench isolation region on the substrate; and
6) forming a field oxide layer in the shallow trench isolation region of the substrate.

In the method according to the invention, the substrate can be a silicon substrate, or germanium, indium phosphide, gallium arsenide or other semiconductor material can be selected as the material of the substrate as needed in practice. In the invention, the pad oxide layer can be formed on the substrate in a conventional process, for example, thermal oxidation, deposition, etc. The pad nitride layer is typically with a thickness of 200-500 Å and can be of a conventional material, for example, silicon oxide, so the pad nitride layer is typically also a silicon oxide layer primarily configured to avoid the subsequently formed nitride layer from damaging the surface of the substrate due to a stress.

In the method according to the invention, the step 2) particularly includes:
forming a nitride layer on the pad oxide layer;
coating the nitride layer with photo-resist, and exposing photo-resist using a mask with the isolation region pattern, and developing photo-resist to form a photo-resist layer with the isolation region pattern; and
etching the nitride layer using the photo-resist layer with the isolation region pattern as a mask to form a barrier layer with the isolation region pattern exposing the surface of the pad oxide layer.

Furthermore the nitride layer can be formed on the pad oxide layer in a conventional method, for example, deposition, and the nitride layer is typically with a thickness of 1500-3000 Å and can be of a conventional material, for example, silicon nitride, and it is primarily configured to protect the silicon substrate located below it from being oxidized, so that the silicon substrate will be locally oxidized only in the area of the isolation region pattern to form the field oxide layer.

Furthermore the thickness of the photo-resist layer of the invention can be 7000-26000 Å, and in a particular implementation, the thickness of the photo-resist layer can be 10000-15000 Å, e.g., 13000 Å, and the photo-resist layer with a specific thickness can prevent the ions in the subsequent process of injecting the ions from penetrating the photo-resist layer and entering the nitride layer and the substrate below the photo-resist layer; and at this time the formed barrier layer is the nitride layer coated with photo-resist which will be removed immediately after the ions are injected, that is, the ions are injected into the formed barrier layer with the isolation region pattern so that the ions enter the substrate through the surface of the pad oxide layer exposed by the isolation region pattern and then the photo-resist layer is removed.

In the method according to the invention, the ions can be injected in a conventional method, and the ions are nitrogen ions formed from source gas including nitrogen-containing gas, for example, chlorine trifluoride (NF₃), ammonia (NH₃), nitrogen dioxide (NO₂), etc. The ions are injected at 30-50 keV, and in this range, the ions can be injected at a maximum depth (i.e., a maximum depth into the substrate) in the range of 0.05-0.1 μm, and this depth range can prevent longitudinal diffusion of the ions in the substrate during subsequent heat treatment from being too deep or shallow to thereby facilitate subsequent etching as well as formation of the field oxide layer; and the ions are injected at a dosage of 10¹⁴-10¹⁵/cm², and this dosage can ensure transverse diffusion of the ions to the specific area (that is, the area in which the beck is formed) during subsequent heat treatment.

In the method according to the invention, the heat treatment is particularly thermal progression (or thermal annealing) which is performed in a nitrogen atmosphere at 1000-1100° C. for 60-90 minutes. This temperature and duration ranges can ensure transverse diffusion of the ions in the substrate in the range of 0.07-0.13 μm, which is the range of the area in which the beck is formed, and this area can be doped with the ions to prevent or hinder oxidation of the silicon substrate in the doped area to thereby prevent or lower the beck from growing. Moreover the temperature and duration ranges can prevent the ions in the substrate from being longitudinally diffused downward below a depth of 0.2 μm to thereby facilitate subsequent etching for formation of the shallow trench isolation region. Since the ions are diffused in the pad oxide layer at a speed far below their diffusion speed in the substrate, the ions will substantially not be transversely diffused in the pad oxide layer.

In the method according to the invention, the pad oxide layer and the ion injection layer are etched using the barrier layer with the isolation region pattern as a mask to form the shallow trench isolation region on the substrate, where the depth of the formed shallow trench isolation region is ≦0.2 μm, and in a particular implementation, the depth of the shallow trench isolation region is 0.15-0.2 μm; and at this time, there is an ion injection layer present only around the shallow trench isolation region at 0.07-0.13 μm for the purpose of preventing the beck from growing. In the invention, etching can be performed in a conventional method, for example, dry etching.

In the method according to the invention, the field oxide layer is formed in the shallow trench isolation region of the substrate in a conventional method, and the field oxide layer is typically with a thickness of 2500-15000 A and can be of a conventional material, for example, silicon oxide. In a particular embodiment, the field oxide layer (the silicon oxide layer) with a thickness of 50500-10000 A is formed through wet oxidation, and the field oxide layer with a different thickness can be grown by controlling the temperature and duration of oxidation, for example, wet oxidation using H₂ at a flow of 6 L/min and O₂ at a flow of 4 L/min at temperature of 950° C. for 225 minutes to form the field oxide layer with a thickness of 0.6 gm (i.e., 6000 Å)

The method according to the invention can be widely applicable to manufacturing of Metal Oxide Semiconductor (MOS) devices, for example, a Vertical Double-diffused Metal Oxide Semiconductor (VDMOS), Horizontal Double-diffused Metal Oxide Semiconductor (LDMOS), a Complementary Metal Oxide Semiconductor (CMOS), a BCD semiconductor, etc.

An implementation of the inventive solution has at least the following advantages:
1. The method of manufacturing a semiconductor device according to the invention is easy to implement in that a beck can be prevented from growing and the length of the beck in the traditional process can be significantly lowered simply by arranging an ion injection layer around the shallow trench isolation region of the substrate; and

In the inventive method, it is not necessary lower the thicknesses of the pad oxide layer and the field oxide layer, so there will be no adverse influence imposed on the semiconductor device, and the length of the beck being significantly lowered can effectively ensure the area of the active area in the semiconductor device and improve the integration level of the semiconductor device, and the inventive method can be widely applicable to MOS manufacturing processes.

### BRIEF DESCRIPTION OF THE DRAWINGS

FIG. 1 is a schematic structural diagram of a cross section of the semiconductor device prepared in the convention LOCOS process; and

FIG. 2 to FIG. 10 are schematic structural diagrams of cross sections of a semiconductor device prepared in a method according to an embodiment of the invention.

### LISTED REFERENCE NUMBERS

1: substrate; 2: pad oxide layer; 3: nitride layer; 4: photo-resist layer; 5: ion injection layer; and 6: field oxide layer.

### DETAILED DESCRIPTION OF THE EMBODIMENTS

In order to make the objects, technical solutions and advantages of the invention more apparent, a technical solution in embodiments of the invention will be described below clearly and fully with reference to the drawings and embodiments of the invention, and apparently the described embodiments are a part but not all of embodiments of the invention. Those ordinarily skilled in the art can derive based the embodiment of the invention here other embodiments without any inventive effort and without departing from the scope of the invention.

### First Embodiment

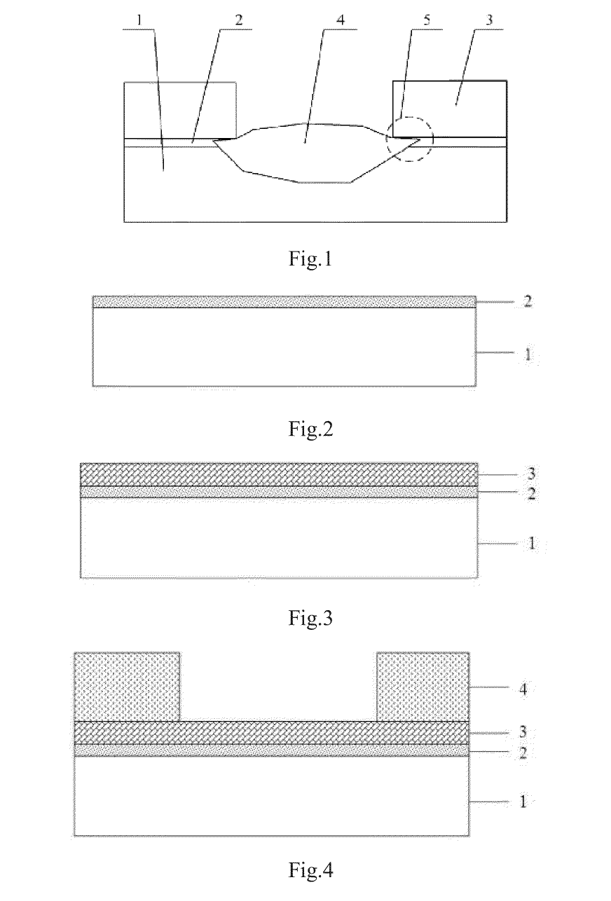

Step 1: As illustrated in FIG. 2, a silicon substrate 1 is oxide in a thermal oxide process so that a pad oxide layer 2 (i.e., a silicon oxide layer 2) with a thickness of 200-500 Å is grown on the silicon substrate 1;

Step 2: As illustrated in FIG. 3, a nitride layer 3 (i.e., a silicon nitride layer) with a thickness of 1500-3000 Å is grown on the pad oxide layer 2 in a chemical vapor deposition process;

Step 3: As illustrated in FIG. 4, photo-resist is applied on the nitride layer 3 and exposed using a mask defined with an isolation region pattern and developed to form a photo-resist layer 4 with the isolation region pattern with a thickness of 10000-15000 Å;

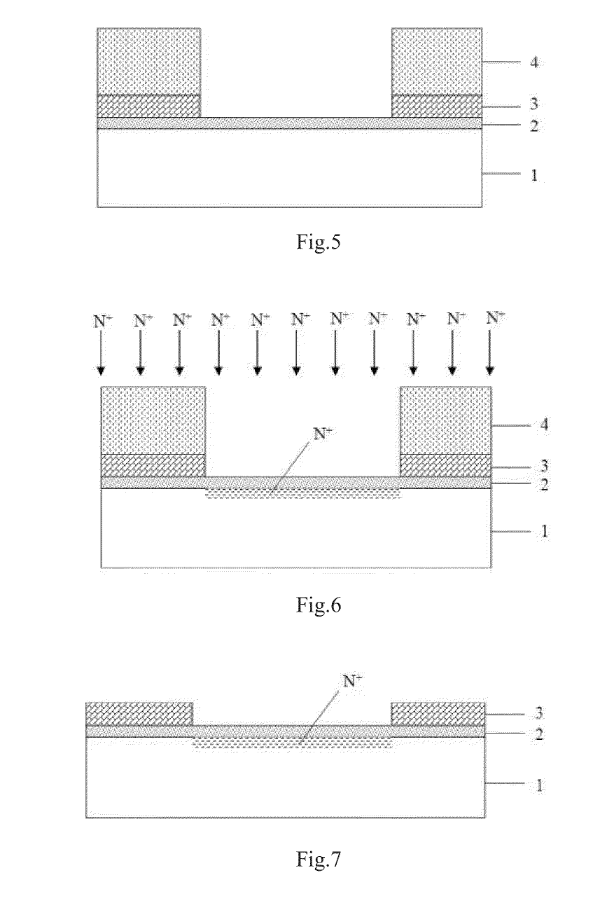

Step 4: As illustrated in FIG. 5, dry etching is performed using the photo-resist layer 4 with the isolation region pattern as a mask to remove nitride inside the area of the isolation region pattern to expose the surface of the pad oxide layer 2 (expose the surface) in the isolation region pattern to thereby form a barrier layer with the isolation region pattern (i.e., the nitride layer coated with photo-resist);

Step 5: As illustrated in FIG. 6, ions are injected using an ion injection machine which firstly converts source gas (nitrogen-containing gas) into the ions (nitrogen ions) at 30-50 keV and then injects the ions vertically in the barrier layer with the isolation region pattern at a dosage of 10¹⁴-10¹⁵/cm² at room temperature, where the ions subsequently enter the photo-resist layer and also enter the pad oxide layer and the substrate through the exposed surface (the ions will not enter the pad oxide layer and the substrate below the thick photo-resist layer);

Step 6: As illustrated in FIG. 7, the photo-resist layer 4 below the pad oxide layer 3 is removed;

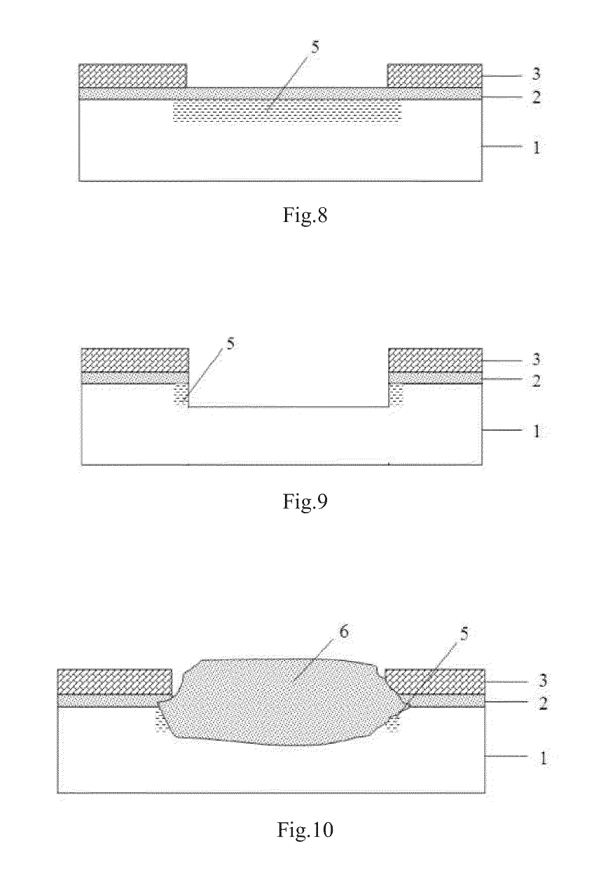

Step 7: As illustrated in FIG. 8, the silicon substrate prepared as above is thermally treated in a nitrogen atmosphere at 1000-1100 □ for 60-90 minutes so that the ions in the substrate are diffused transversely by 0.07-0.13 μm and longitudinally downward by no more than 0.2 μm to thereby form an ion injection layer 5 (the ions will substantially not be diffused transversely in the pad oxide layer because they are diffused in the pad oxide layer at a speed far below that in the substrate);

Step 8: As illustrated in FIG. 9, the pad oxide layer and the ion injection layer are etched using the barrier layer with the isolation region pattern to form a shallow trench isolation region with a depth of 0.15 to 0.2 μm on the substrate; and

Step 9: As illustrated in FIG. 10, the substrate prepared as above is wet-oxidized using H₂ at a flow of 6 L/min and O₂ at a flow of 4 L/min at temperature of 950° C. for 225 minutes to form a field oxide layer 6 (of silicon oxide) with a thickness of 0.6 μm in the shallow trench isolation region, thus manufacturing a semiconductor device according to the invention.

The semiconductor device manufactured in the method according to the invention includes: the substrate 1 arranged thereon with the shallow trench isolation region around which the ion injection layer 5 is arranged; the pad oxide layer 2, located on the substrate 1, with the isolation region pattern exposing the shallow trench isolation region; the nitride layer 3, located on the pad oxide layer 2, with the isolation region pattern exposing the shallow trench isolation region (that is, the nitride layer 3 and the pad oxide layer 2 are arranged in matching areas); and the field oxide layer 6 located in the shallow trench isolation region, where the ion injection layer extends transversely outward by 0.07-0.13 μm around the shallow trench isolation region.

Since the ion injection layer is arranged in the area in which a beck is formed, the injected ions can prevent or hinder oxidation of the silicon substrate in this area to thereby prevent or lower growing of the beck.

A detected length of the beck in a slice of the manufactured semiconductor device showed a 0.15-μm length of the beck in the semiconductor device manufactured in the method of this embodiment.

### Second Embodiment

Step 1 to Step 8 are the same as those in the first embodiment;

Step 9: The substrate prepared as above is wet-oxidized using H₂ at a flow of 6 L/min and O₂ at a flow of 4 L/min at temperature of 1000° C. for 350 minutes to form the field oxide layer with a thickness of 1.0 μm in the shallow trench isolation region, thus manufacturing the semiconductor device according to the invention, and the length of the beck was detected as 0.25 μm.

### Comparative Example 1

Step 1 to Step 4 are the same as those in the first embodiment;

Step 5: The photo-resist layer above the nitride layer is removed; and

Step 6: The substrate prepared as above is wet-oxidized using H₂ at a flow of 6 L/min and O₂ at a flow of 4 L/min at temperature of 950° C. for 225 minutes to form the field oxide layer with a thickness of 0.6 μm, and the length of the beck was detected as 0.3 μm.

### Comparative Example 2

Step 1 to Step 4 are the same as those in the first embodiment;

Step 5: The photo-resist layer above the nitride layer is removed; and

Step 6: The substrate prepared as above is wet-oxidized using H₂ at a flow of 6 L/min and O₂ at a flow of 4 L/min at temperature of 1000° C. for 350 minutes to form the field oxide layer with a thickness of 1.0 μm, and the length of the beck was detected as 0.5 μm.

Lastly it shall be noted that the foregoing respective embodiments are merely illustrative of the technical solution of the invention but not to limit the same; and although the invention has been detailed above in connection with the foregoing embodiments, those ordinarily skilled in the art shall appreciate that they can modify the technical solution disclosed in the foregoing respective embodiments or make equivalent substitutions for a part or all of the technical features without departing from the scope of the invention.

1. A semiconductor device, comprising:
a substrate with a shallow trench isolation region arranged thereon, wherein an ion injection layer is arranged around the shallow trench isolation region;
a pad oxide layer, located on the substrate, with an isolation region pattern exposing the shallow trench isolation region;
a barrier layer, located on the pad oxide layer, with the isolation region pattern exposing the shallow trench isolation region; and
a field oxide layer located in the shallow trench isolation region.

2. The semiconductor device according to claim 1, wherein the ion injection layer extends transversely outward by 0.07-0.13 μm around the shallow trench isolation region.

3. The semiconductor device according to claim 1, wherein the substrate is a silicon substrate, and the barrier layer is a nitride layer.

4. A method of manufacturing the semiconductor device according to claim 1, comprising:
Step 1 of forming a pad oxide layer on a substrate;
Step 2 of forming on the pad oxide layer a barrier layer with an isolation region pattern exposing a surface of the pad oxide layer;
Step 3 of injecting ions so that the ions enter the substrate through the surface of the pad oxide layer exposed by the isolation region pattern;
Step 4 of performing heat treatment the substrate to transversely diffuse the ions in the substrate to form an ion injection layer;
Step 5 of etching the pad oxide layer and the ion injection layer using the barrier layer with the isolation region pattern as a mask to form a shallow trench isolation region on the substrate; and
Step 6 of forming a field oxide layer in the shallow trench isolation region of the substrate.

5. The method according to claim 4, wherein the ions are transversely diffused in the substrate in a range of 0.07-0.13 μm.

6. The method according to claim 4, wherein the ions are nitrogen ions and injected at 30-50 keV at a dosage of 1014-1015/cm2.

7. The method according to claim 4, wherein the heat treatment is performed in a nitrogen atmosphere at 1000-1100° C. for 60-90 minutes.

8. The method according to claim 4, wherein the Step 2 further comprises:
forming a nitride layer on the pad oxide layer;
coating the nitride layer with photo-resist, and exposing photo-resist using a mask with the isolation region pattern, and developing photo-resist to form a photo-resist layer with the isolation region pattern; and
etching the nitride layer using the photo-resist layer with the isolation region pattern as a mask to form a barrier layer with the isolation region pattern exposing the surface of the pad oxide layer.

9. The method according to claim 8, wherein:
the ions are injected into the formed barrier layer with the isolation region pattern so that the ions enter the substrate through the surface of the pad oxide layer exposed by the isolation region pattern, and the photo-resist layer are removed.

10. The method according to claim 4, wherein the thickness of the shallow trench isolation region is ≦0.2 μm.

11. The method according to claim 4, wherein material of the pad oxide layer is silicon oxide, material of the nitride layer is silicon nitride, and material of the field oxide layer is silicon oxide.

12. The semiconductor device according to claim 1, wherein ions injected into the ion injection layer are nitrogen ions.
